(19) United States
(12) Patent Application Publication
(10) Pub. No.: US 2010/0136488 A1
(43) Pub. Date: Jun. 3, 2010

(54) PATTERN CREATION METHOD, SEMICONDUCTOR DEVICE MANUFACTURING METHOD, AND COMPUTER-READABLE STORAGE MEDIUM

(76) Inventor: Kazuya FUKUHARA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/548,085

(22) Filed: Aug. 26, 2009

(30) Foreign Application Priority Data
Nov. 28, 2008 (JP) 2008-304132

(51) Int. Cl. G03F 7/20; G06F 17/50

(52) U.S. Cl. 430/319; 716/21

(57) ABSTRACT

A pattern creation method has extracting a first pattern and a second pattern which are different from each other from among first mask patterns created based on a first design pattern, calculating a best focus difference between the first pattern and the second pattern based on first exposure conditions, comparing the best focus difference to a predetermined threshold value, and if the best focus difference is larger than the threshold value, correcting the first design pattern to create a second design pattern.

### CROSS REFERENCE TO RELATED APPLICATION

This application is based upon and claims benefit of priority from the Japanese Patent Application No. 2008-304132, filed on Nov. 28, 2008, the entire contents of which are incorporated herein by reference.

### BACKGROUND OF THE INVENTION

The present invention relates to a pattern creation method, a semiconductor device manufacturing method, and a computer-readable storage medium.

As the size or the pitch of a pattern to be transferred gets near to the limit of resolution of an exposure device, the amount of change in size increases with respect to an error in amount of exposure and an error in focusing. It may be desirable not to use the patterns with difficult requirements for dimensional accuracy with respect to performance of the exposure device, that is, exposure amount control accuracy and focus control accuracy. Information about definitions of pattern types that can be allowed in circuit pattern design as described above may be referred to as design rules. The design rules describe, for example, a combination of the lines and the spaces of line patterns that can be used in pattern design (see, for example, Japanese Patent Application Laid-Open No. 2001-14376).

In manufacturing of semiconductor devices, fine patterns having a half pitch of about 45 nm may be formed by using a projection optical system having a transfer scale factor of ¼ and exposure light having a wavelength of 193 nm, for example. In this case, the half pitch of mask patterns is 180 nm, which is shorter than the wavelength of the exposure light. Further, there may be a case where illuminating light to illuminate the mask patterns is used which is obliquely incident having an incident angle of up to about 20 degrees. Under such conditions, approximation of assuming the mask pattern to be a simple thin film object is not enough to explain the state of diffraction of light. In view of this, a necessity has been pointed out to calculate the diffraction of light based on analysis of a rigorous electromagnetic field taking into account the 3-D structure of the mask patterns (see, for example, “Modeling Oblique Incidence Effects in Photo-masks” by Tom V Pistor, Optical Microlithography XIII, SPIE Vol. 4000, pp. 228-237, 2000). Hereinafter, a phenomenon that occurs owing to the 3-D structure of mask patterns is referred to as “mask 3D effect”.

In another example, fine patterns having a half pitch of about 32 nm may be formed by using a projection optical system constituted of a mirror optical system using extreme UV (EUV) having a wavelength of 13.5 nm as exposure light and a reflective mask and having a transfer scale factor of ¼, for example. In this case, although the half pitch of mask patterns is sufficiently larger than the wavelength, the reflective mask used will be illuminated in a condition where the optical axis of illumination light is inclined by 6-8 degrees with respect to the normal line of the plane of the mask pattern. It is known that even under those conditions, the mask 3D effect need to be taken in account in order to properly explain the behavior of a formed image.

As a result of recent researches, it has been made clear that as a phenomenon due to the mask 3D effect in formation of resist patterns, the best focus wafer position changes (hereinafter referred to as inter-pattern best focus difference) depending on the shapes of the patterns, especially the integration density thereof. This may be caused by the occurrence of a difference in phase between a plurality of diffracted lights generated at the mask. In more detail, a difference in phase will occur between the zeroth-order diffracted light and the first-order diffracted light owing to the mask and change depending on a pitch of the patterns, which phenomenon cannot be predicted by the thin film object approximation.

If an inter-pattern best focus difference occurs between at least two types of patterns having a small focus depth on the same mask, it becomes difficult to satisfy the requirements of dimensional accuracy of those patterns simultaneously, which gives rise to a problem that the production yield of the semiconductor devices may be deteriorated.

### SUMMARY OF THE INVENTION

According to one aspect of the present invention, there is provided a pattern creation method comprising:

extracting a first pattern and a second pattern which are different from each other from among first mask patterns created based on a first design pattern;

calculating a best focus difference between the first pattern and the second pattern based on first exposure conditions;

comparing the best focus difference to a predetermined threshold value; and

if the best focus difference is larger than the threshold value, correcting the first design pattern to create a second design pattern.

According to one aspect of the present invention, there is provided a pattern creation method comprising:

extracting a first pattern and a second pattern which are different from each other from among first mask patterns created based on a first design pattern;

calculating a first best focus difference that provides a best focus difference between the first pattern and the second pattern based on first exposure conditions;

changing the first exposure conditions to obtain second exposure conditions;

calculating a second best focus difference that is smaller than the first best focus difference and provides a best focus difference between the first pattern and the second pattern based on the second exposure conditions;

comparing the second best focus difference to a predetermined threshold value; and

if the second best focus difference is larger than the threshold value, correcting the first design pattern to create a second design pattern.

According to one aspect of the present invention, there is provided a semiconductor device manufacturing method, wherein exposure is performed by using a mask corresponding to a design pattern created by the pattern creation method so as to create patterns on a semiconductor substrate.

According to one aspect of the present invention, there is provided a computer-readable storage medium storing a pattern verification program, wherein the pattern verification program causes a computer to execute the steps of:

extracting a first pattern and a second pattern which are different from each other from among first mask patterns created based on a first design pattern;

calculating a best focus difference between the first pattern and the second pattern based on first exposure conditions; and

comparing the best focus difference to a predetermined threshold value.

### BRIEF DESCRIPTION OF THE DRAWINGS

FIG. 1 is an explanatory flowchart of a pattern creation method according to an embodiment of the present invention;

FIG. 2 is a table showing one example of design rules;

FIG. 3 is a diagram showing one example of a resist stack structure;

FIG. 4 is an explanatory flowchart of the pattern creation method according to a variant;

FIG. 5A is a diagram showing one example of the pre-change film thickness of the resist stack structure;

FIG. 5B is a diagram showing one example of the post-change film thickness of the resist stack structure;

FIG. 6 is another explanatory flowchart of the pattern creation method according to the variant;

FIG. 7A is a table showing one example of the pre-change design rules;

FIG. 7B is a table showing one example of the post-change design rules; and

FIG. 8 is a block diagram of a pattern creation device.

### DESCRIPTION OF THE EMBODIMENTS

A description will be given of an embodiment of the present embodiments with reference to the drawings.

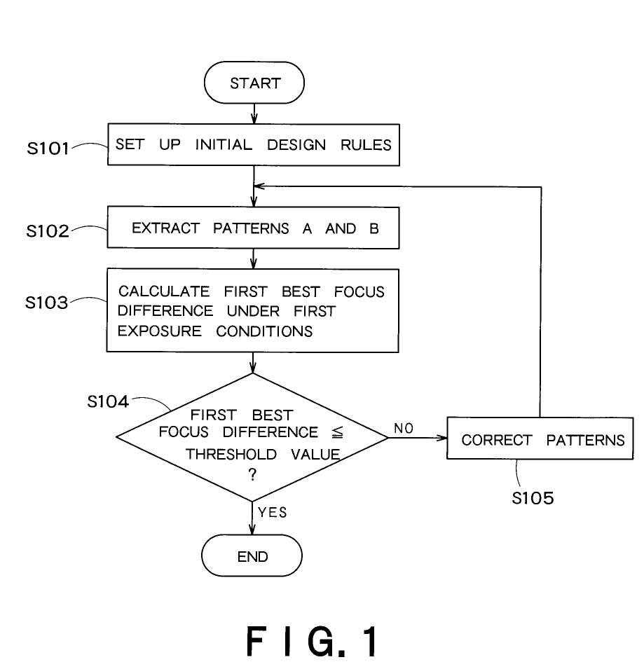

FIG. 1 shows an explanatory flowchart of a pattern creation method according to an embodiment of the present invention.

(Step S101) Initial design rules are set. For example, a maximum value and a minimum value of each of a line (L) width and a space (S) width in a line-and-space pattern (L/S pattern) are prescribed, which provides a basis for a layout pattern.

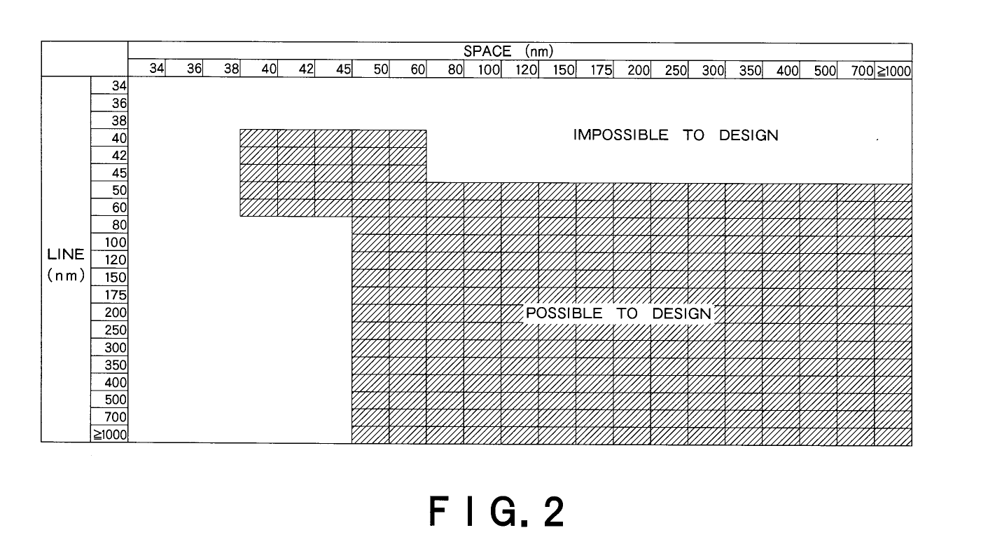

Then, values between the maximum and minimum values are prescribed by using a predetermined pitch, to detect as to whether an optical image can be dissected (designed) for each of the combinations of the line widths and the space widths. In such a manner, a matrix of design rules (initial design rules) such as shown in FIG. 2 are obtained. A shaded portion in FIG. 2 covers the combinations of the line widths and the space width that enable designing.

It is to be noted that whether an optical image can be dissected may be decided through optical simulation or by observing a pattern formed by actual exposure.

Then, a first design pattern that satisfies the initial design rules is created. Subsequently, a mask pattern that corresponds to the first design pattern is created taking into account an amount of correction by optical proximity correction (OPC). An OPC program which is utilized in the mask pattern creation step will perform process simulation that utilizes either one of a simulation model not taking into account the mask 3D effect (thin film approximate model), a simulation model taking into account the mask 3D effect (rigorous calculation model), and a thin film approximate model including the mask 3D effect through simple approximation.

(Step S102) Two patterns A and B are extracted from the patterns included in the mask patterns. For example, the mask pattern that corresponds to a pattern having small line width and space width from the first design patterns is extracted as pattern A, and the mask pattern that corresponds to a pattern having a small line width and a large space width from the first design patterns is extracted as pattern B.

(Step S103) Exposure simulation under initial exposure conditions (first exposure conditions) is performed and a best focus position for each of patterns A and B is calculated, thus obtaining a best focus difference (first best focus difference).

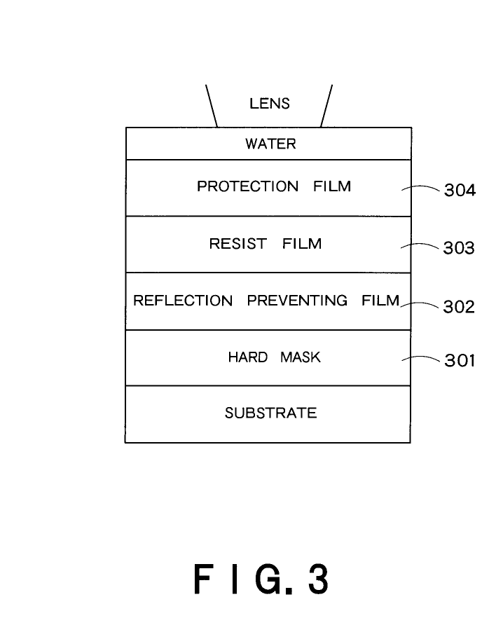

The exposure conditions include a projection lens aberration, a resist stack structure and the like. The exposure conditions about the resist stack structure include a film thickness, a material type, a refractive index, an extinction coefficient, and the like of each of a hard mask 301, a reflection preventing film 302, a resist film 303, and a protection film 304 which are formed on a film to be processed 300 during exposure such as shown in FIG. 3. It is to be noted that these hard mask 301, reflection preventing film 302, resist film 303, and protection film 304 are each of a single layer structure or a stack structure.

The calculation of the best focus position involves simulation calculations to obtain an intensity distribution of light that is focused by a projection optical system. In this case, the light reflected by an interface below the resist film 303 of the resist stack structure may be reflected in the light intensity distribution in the resist film 303 by using an algorithm (for example, transfer matrix method) that reproduces the multiple interference effect caused by light reflection at each of the interfaces in the multilayer film system.

(Step S104) The first best focus difference is compared to a predetermined threshold value. If the first best focus difference is larger than the predetermined threshold value, the processing goes to step S105 and, if it is not larger than the threshold value, the processing ends.

Generally, the exposure devices will be set up in such a manner that the total sum of focus difference such as a best focus difference, a device machine accuracy, an optical error, a substrate irregularity, a mask substrate flatness, etc. may be smaller than a maximum focus depth obtained optically (obtained by calculations from illumination conditions and pattern shapes). Accordingly, the aforesaid threshold value will be established so as to satisfy this relationship taking into account the other error factors such as the device machine accuracy.

For example, in the case of a liquid immersion exposure device having NA=1.3, the total sum of the focus errors will be set so as to be smaller than 90-110 nm, the best focus difference amount of which, that is, the threshold value will be set to 10-20 nm.

(Step S105) The first design pattern is corrected to create a second design pattern. For example, the line width of the pattern having the small line width and a large space width is enlarged by an arbitrary amount among the first design patterns that correspond to the mask pattern extracted as pattern B at step S102. Then, a mask pattern that corresponds to the second design pattern is created taking into account an amount of correction by OPC and the processing returns to step S102. Then, processing of steps S103 and S104 is performed on this mask pattern.

Thus, at the stage of pattern designing, the design pattern may be corrected so that the best focus difference at the time of exposure may not be out of an allowable range.

Then, a mask that corresponds to this design pattern (post-correction design pattern if the pattern is corrected) may be created utilizing OPC and used to perform exposure under the exposure conditions (first exposure conditions) set up for the exposure simulation at step S103; in such a manner, resist patterns having desired dimensional accuracy can be formed, thus manufacturing a semiconductor device having circuit patterns of desired dimensions.

Thus, the present embodiment will correct a design pattern until the best focus difference is reduced sufficiently (down to the threshold value or less). A mask will be created which has mask patterns that correspond to the design pattern thus created and used in exposure, to inhibit an inter-pattern best focus difference and improve the resist dimensional accuracy, thereby improving the production yield of the semiconductor devices.

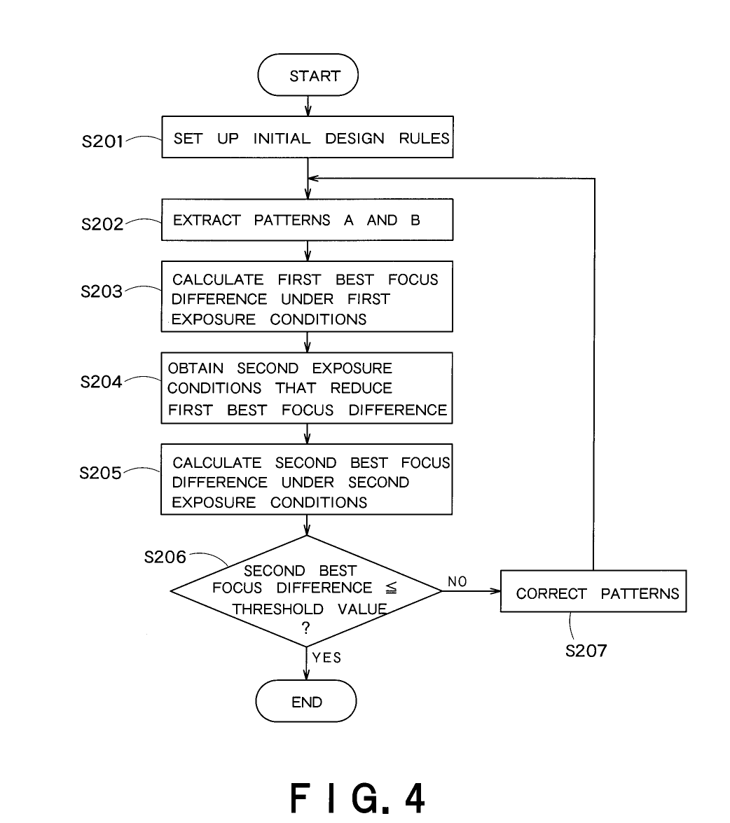

Although the embodiment has employed the initial exposure conditions (first exposure conditions) as they are without changing them, not only the design pattern may be corrected but also the exposure conditions may also be adjusted. By adjusting the exposure conditions, the best focus difference may be reduced more easily than the case of only correcting the design pattern. A description will be given of a method for creating a design pattern in the case of exposure conditions adjustment with reference to a flowchart of FIG. 4. It is to be noted that steps S201-203 are the same as steps S101-103 respectively in FIG. 1, and description on the identical steps will not be repeated.

(Step S204) First exposure conditions are adjusted to obtain such second exposure conditions as to reduce the first best focus difference. For example, the spherical aberration of the projection optical system is changed. This is because that only by changing the spherical aberration, the best focus position will change by an amount that depends on the type of the pattern.

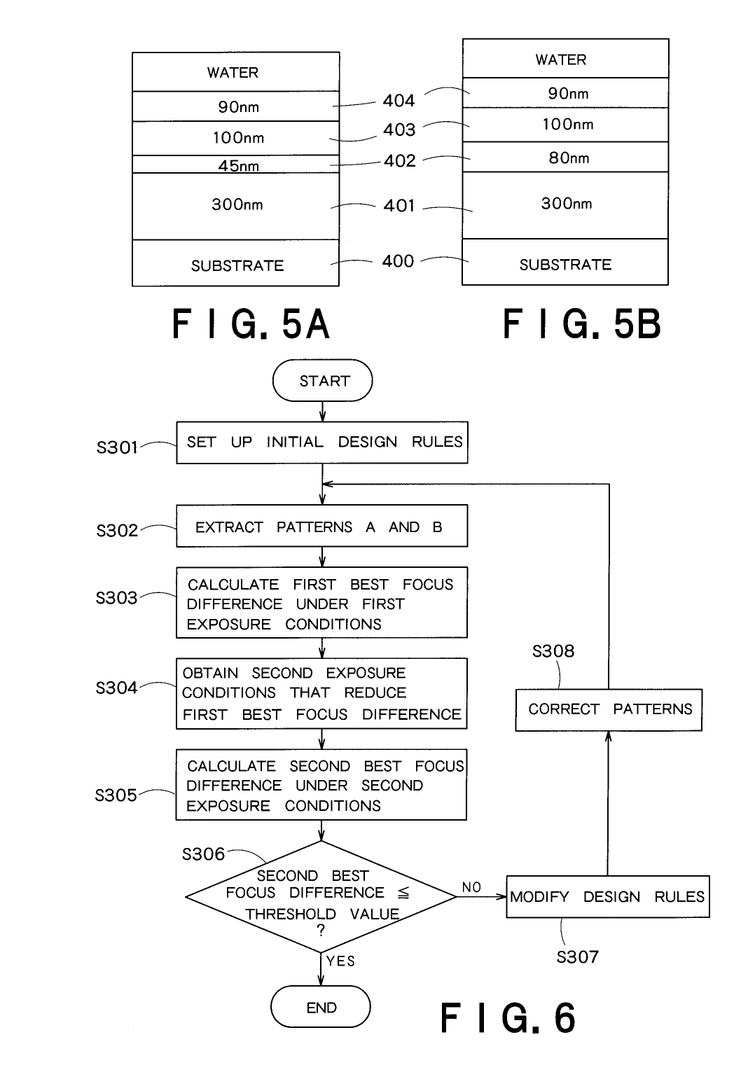

Further, the resist stack structure may be changed. One example of a change in best focus difference caused by a change in resist stack structure is shown in FIG. 5. It is assumed that pattern A is a mask pattern that corresponds to an L/S pattern of line width 90 nm and pitch 200 nm, while pattern B is a mask pattern that corresponds to an isolated pattern of line width 250 nm.

As shown in FIG. 5A, a layer (opaque layer) 401 having a film thickness of 300 nm, a layer 402 having a film thickness of 45 nm, a layer (resist film) 403 having a film thickness of 100 nm, and a layer (protection film) 404 having a film thickness of 90 nm were sequentially stacked on a substrate 400; in the case of the resist stack structure, the best focus difference was 15 nm between pattern A and pattern B.

It is to be noted that the dimensions of the patterns formed during exposure were measured as changing a focus offset, to calculate a curve of the second order that approximates a focus versus dimensional curve obtained by the measurement, thus obtaining a best focus position (best focus difference). For example, the best focus value refers to such a focus value as to provide the smallest change in dimension with respect to a change in focus along that curve of the second order.

As shown in FIG. 5B, the film thickness of the layer 402 was changed (increased) to 80 nm and exposure was performed almost in the same way, to come up with nearly the same values of the best focus positions of patterns A and B. Therefore, the best focus difference can be reduced by adjusting the film thickness of the film below the resist film.

Although this example has changed the film thickness of the film below the resist film, also by changing the film thickness of the resist film, the optical constant of the resist film, the optical constant of the film below the resist film, etc., the best focus positions of patterns A and B can be changed, thus reducing the best focus difference. The optical constant may be the refractive index or the extinction coefficient with respect to the wavelength of light. Further, the reflection ratio may be changed at the interface between the resist film and the under-layer film.

(Step S205) Exposure simulation is performed under the initial exposure conditions (second exposure conditions) obtained at step S204 and a best focus position for each of patterns A and B is calculated, thus obtaining a best focus difference (second best focus difference).

(Step S206) The second best focus difference is compared to the predetermined threshold value. If the second best focus difference is larger than the predetermined threshold value, the processing goes to step S207 and, if it is not larger than the threshold value, the processing ends.

It is to be noted that if the spherical aberration of the projection optical system is assumed to be able to be changed by an arbitrary amount at step S204, the aforesaid second best focus difference must be zero always. However, in the actual exposure devices, the range in which the spherical aberration can be changed is limited by a variety of constraints (for example, the overall size of the projection optical system must be a constant value or less) in optical design. Therefore, the second best focus difference cannot always be reduced to 0. In other words, preferably, the amount of changes in spherical aberration of the projection optical system at step S204 may be in a range enabled for the exposure device which is used.

(Step S207) The first design pattern is corrected to create a second design pattern. For example, the line width of the pattern having the small line width and a large space width is enlarged by an arbitrary amount among the first design patterns that correspond to the mask pattern extracted as pattern B at step S202. Then, a mask pattern that corresponds to the second design pattern is created by adding to it an amount of correction by OPC and the processing returns to step S202. Then, processing of steps S202-206 is performed on this mask pattern.

Thus, at the stage of mask pattern designing, the exposure conditions will be adjusted and the design pattern will be corrected so that the best focus difference at the time of exposure may not be out of an allowable range.

Then, a mask that corresponds to this design pattern (post-correction design pattern if the pattern is corrected) may be created utilizing OPC and used to perform exposure under the exposure conditions (second exposure conditions) set up for the exposure simulation at step S205, thus forming resist patterns having desired dimensional accuracy.

Thus, the present example will adjust exposure conditions and correct a design pattern until the best focus difference is reduced sufficiently (down to the threshold value or less). A mask will be created which has mask patterns that correspond to the design pattern thus created and used in exposure under the post-adjustment exposure conditions, to inhibit an inter-pattern best focus difference and improve the resist dimensional accuracy, thereby improving the production yield of the semiconductor devices.

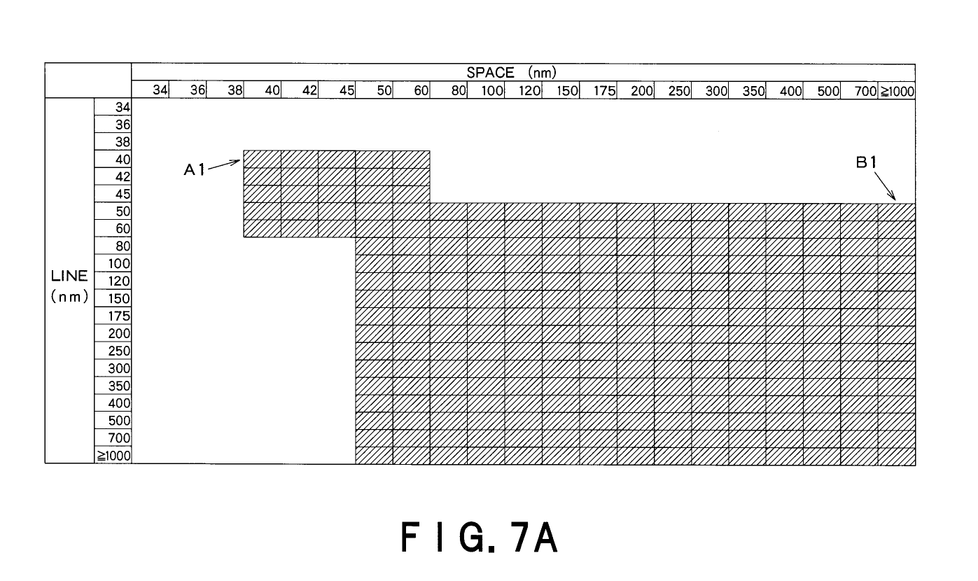

Further, the design pattern correction shown in FIG. 1 or 4 may involve further modification of the design rules. As an example, the design pattern creation method in the case of modifying the design rules in the design pattern correction shown in FIG. 4 will be described with reference to a flowchart shown in FIG. 6. It is to be noted that steps S301-306 are the same as steps S201-206 respectively in FIG. 4, and description on the identical steps will not be repeated.

(Step S307) Modify the design rules so that design pattern that corresponds to pattern A and/or pattern B may not be allowed in design (nonuse patterns).

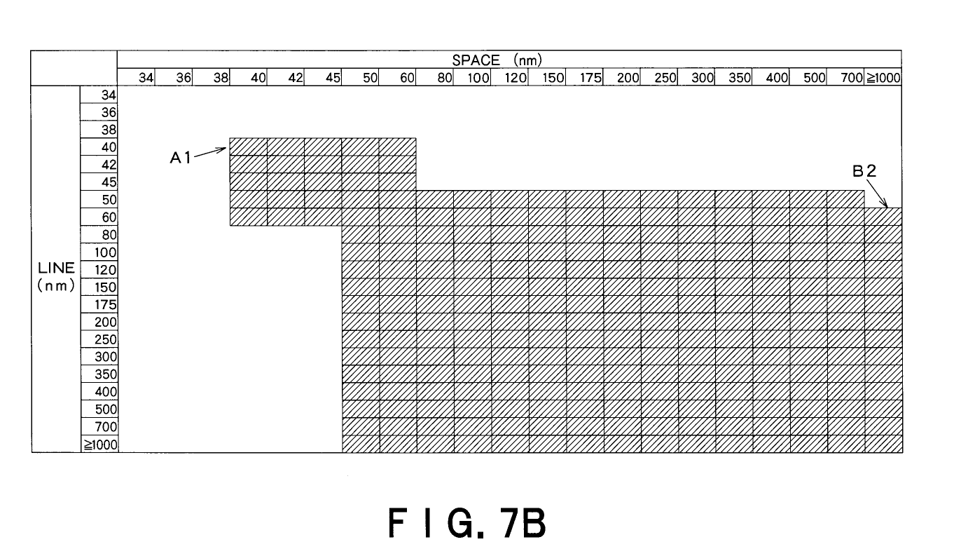

For example, assume that in the initial design rules shown in FIG. 7A, the size of the design patterns corresponding to pattern A corresponds to the portion of A1 and the size of the design patterns corresponding to pattern B corresponds to the portion of B1. In this case, if the design patterns corresponding to pattern B are rendered unallowable, the portion of B1 is rendered unusable, thus providing post-modification design rules such as shown in FIG. 7B.

(Step S308) The first design patterns are corrected in such a manner as to satisfy the post-modification design rules, thus creating second design patterns. For example, the sizes of patterns in the first design patterns corresponding to the mask pattern extracted as pattern B at step S302 are changed to those that correspond to the portion of B2 shown in FIG. 7B.

Then, a mask pattern that corresponds to the second design patterns is created taking into account the correction by OPC and the processing returns to step S302. Then, processing of steps S302-306 is performed on this mask pattern.

In such a manner, the design rules are modified so as to invalidate the use of the pattern size of design patterns corresponding to such a mask pattern that the best focus difference cannot sufficiently be reduced even by optimization of the aberration of the projection optical system or the resist stack structure, so that based on the modified design rules, a design pattern may be created (corrected).

By performing exposure under the second exposure conditions by using a mask having a mask pattern corresponding to the design pattern thus created, the inter-pattern best focus difference can be inhibited, to improve the resist dimensional accuracy, thereby improving the production yield of the semiconductor devices.

Although the embodiment has obtained a best focus difference by performing exposure simulation, exposure may be actually performed under the first or second exposure conditions, thus correcting the design pattern, adjust the exposure conditions, and modify the design rules based on the result of the exposure.

Although the embodiment has changed the spherical aberration of the projection optical system when obtaining such exposure conditions (second exposure conditions) as to reduce the best focus difference at steps S204 and S304, any other aberrations such as astigmatism or 4θ aberration may be adjusted.

Further, there are some cases where the best focus difference can be reduced also by changing the illumination conditions such as the numerical aperture (NA) of the projection optical system and the distribution of the illumination luminance of a secondary light source.

Since a plurality of shapes of patterns are included in the mask patterns (design patterns), the number of the combinations of patterns A and B extracted at steps S102, S202, and S302 can also be considered to be more than one. Although the embodiment has assumed the number of the combination to be one for ease of explanation, actually, the exposure conditions may be changed or the design rules may be modified so that the best focus difference may be the threshold value or less for a plurality of the combinations.

In the case of defining a design pattern corresponding to either one of patterns A and B as an unallowable pattern at step S307, one of the design patterns which is larger in pitch may be defined as the unallowable pattern. By doing so, an influence of a change in pattern shape (size) may be reduced on the performance of the semiconductor devices.

Further, in a case where pattern A corresponds to densely integrated patterns and pattern B corresponds to isolated patterns, preferably the design rules may be changed at step S307 so as to define the design patterns (isolated patterns) corresponding to pattern B as unallowable patterns. This is because the isolated patterns have no other patterns around them and can be changed in shape easily.

In the case of defining a design pattern corresponding to either one of patterns A and B as an unallowable pattern at step S307, one of the design patterns which is more distant to the adjacent pattern may be defined as the unallowable pattern. By doing so, an influence of a change in pattern shape (size) may be reduced on the performance of the semiconductor devices or the pattern has no other patterns around it and can be changed in shape easily.

Further, the embodiment has not limited the directivity of patterns A and B, in the case of, for example, EUV exposure using a reflective mask, exposure is performed in a condition where the optical axis is inclined with respect to the normal line of the plane of the mask pattern, so that there are some cases where a best focus difference may occur between the pattern having a certain directivity and the pattern rotated by 90 degrees. In this case, step S103 (S203 or S303) and the subsequent may be performed by specifying the aforesaid patterns A and B to be mask patterns corresponding to the design patterns that have the same size but different directivities.

Although the embodiment has extracted two patterns A and B at step S302, at least three mask patterns may be extracted. In this case, it is suitable to define, at step S307, as unallowable patterns those design patterns corresponding to a mask pattern located to a best focus position having the largest difference with respect to an average value of the best focus positions of the patterns.

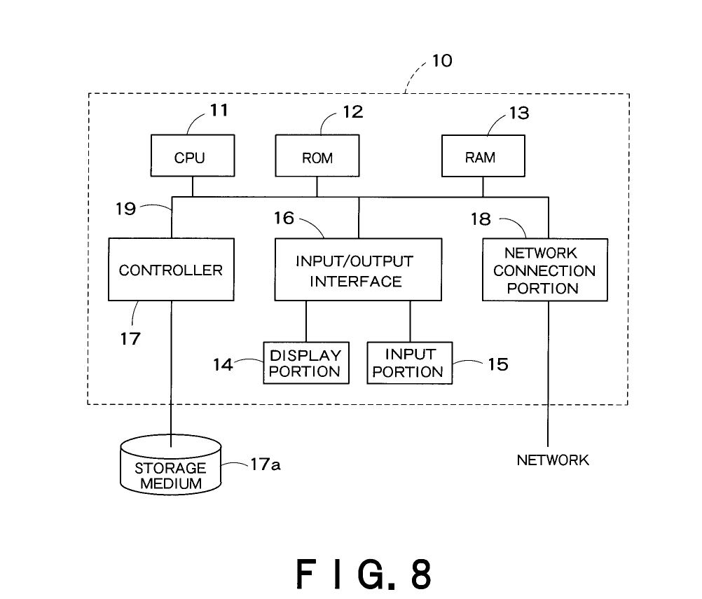

A pattern creation method of the embodiment will be carried out by a pattern creation device such as shown in FIG. 8. The pattern creation device comprises a CPU11, an ROM12, an RAM13, a display portion 14, an input portion 15, an input/output interface 16, a controller 17, and a network connection portion 18, which are connected to each other via a bus line 19.

A pattern creation program (not shown), which is a computer program to create patterns, is stored in a storage medium such as either a storage medium 17a outside the pattern creation device 10, for example, a magnetic disk or an optical disk or a computer (not shown) outside the pattern creation device 10, for example, a server computer or a workstation, or a storage medium inside the pattern creation device 10, for example, the ROM12.

The computer program stored in the storage medium 17a is loaded to the RAM13 via the controller 17 and the bus line 19. On the other hand, the computer program stored in the external server computer or the like is loaded to the RAM13 via the network connection portion 18 and the bus line 19. Further, the computer program stored in the ROM12 is loaded to the RAM13 via the bus line 19.

The CPU11 executes the pattern creation program loaded into the RAM13 and prompts, via the input/output interface 16, the user to enter data such as necessary parameters through the input portion 15, for example, a keyboard, a touch panel, or a mouse. The CPU11 further displays, for example, design data and design drawings on the display portion 14, for example, a display.

As the CPU11 executes the pattern creation program, pattern creation processing such as shown in FIGS. 1, 4, and 6 will be carried out. Further, the CPU11 may be arranged so as to execute a pattern verification program, thus performing processing of steps S101-104 shown in FIG. 1.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern creation method comprising:
extracting a first pattern and a second pattern which are different from each other from among first mask patterns created based on a first design pattern;
calculating a best focus difference between the first pattern and the second pattern based on first exposure conditions;
comparing the best focus difference to a predetermined threshold value; and
if the best focus difference is larger than the threshold value, correcting the first design pattern to create a second design pattern.

2. The pattern creation method according to claim 1, wherein the first pattern and the second pattern are mask patterns created corresponding to the design patterns that have different distances up to their respective adjacent patterns among the first design patterns and, when correcting the first design pattern, either one of the design patterns corresponding to the first pattern and the second pattern which is more distant up to their respective adjacent patterns is corrected.

3. The pattern creation method according to claim 1, wherein if the best focus difference is larger than the threshold value, design rules are modified so as to define the design patterns corresponding to the first pattern or the second pattern as a nonuse pattern to then correct the first design pattern so as to satisfy the post-modification design rules, thus creating a second design pattern.

4. The pattern creation method according to claim 3, wherein the design patterns corresponding to the second pattern that has a larger pitch than the design patterns corresponding to the first pattern are defined as the nonuse pattern.

5. A pattern creation method comprising:
extracting a first pattern and a second pattern which are different from each other from among first mask patterns created based on a first design pattern;
calculating a first best focus difference that provides a best focus difference between the first pattern and the second pattern based on first exposure conditions;
changing the first exposure conditions to obtain second exposure conditions;
calculating a second best focus difference that is smaller than the first best focus difference and provides a best focus difference between the first pattern and the second pattern based on the second exposure conditions;
comparing the second best focus difference to a predetermined threshold value; and
if the second best focus difference is larger than the threshold value, correcting the first design pattern to create a second design pattern.

6. The pattern creation method according to claim 5, wherein the first pattern and the second pattern are mask patterns created corresponding to the design patterns that have different distances up to their respective adjacent patterns among the first design patterns and, when correcting the first design pattern, either one of the design patterns corresponding to the first pattern and the second pattern which is more distant up to their respective adjacent patterns is corrected.

7. The pattern creation method according to claim 5, wherein the first exposure conditions include aberration of a projection optical system of an exposure device, the aberration being adjusted to obtain the second exposure conditions.

8. The pattern creation method according to claim 7, wherein the aberration is at least one of spherical aberration, astigmatism, and 4θ aberration.

9. The pattern creation method according to claim 5, wherein the first exposure conditions include a numeric aperture of the projection optical system of the exposure device or a distribution of an illumination luminance of a secondary light source, the numeric aperture or the illumination luminance distribution being adjusted to obtain the second exposure conditions.

10. The pattern creation method according to claim 5, wherein the first exposure conditions include a resist stack structure having a resist film to be exposed to light and an underlayer film formed below this resist film, the resist stack structure being changed to obtain the second exposure conditions.

11. The pattern creation method according to claim 10, a film thickness or an optical constant of the underlayer film is changed to obtain the second exposure conditions.

12. The pattern creation method according to claim 10, a film thickness or an optical constant of the resist film is changed to obtain the second exposure conditions.

13. The pattern creation method according to claim 5, wherein if the second best focus difference is larger than the threshold value, design rules are modified so as to define the design patterns corresponding to the first pattern or the second pattern as a nonuse pattern to then correct the first design pattern so as to satisfy the post-modification design rules, thus creating a second design pattern.

14. The pattern creation method according to claim 13, wherein the design patterns corresponding to the second pattern that has a larger pitch than the design patterns corresponding to the first pattern are defined as the nonuse pattern.

15. A semiconductor manufacturing method, wherein exposure is performed by using a mask corresponding to a design pattern created by the pattern creation method of claim 1 so as to create patterns on a semiconductor substrate.

16. A computer-readable storage medium storing a pattern verification program, wherein the pattern verification program causes a computer to execute the steps of:
extracting a first pattern and a second pattern which are different from each other from among first mask patterns created based on a first design pattern;
calculating a best focus difference between the first pattern and the second pattern based on first exposure conditions; and
comparing the best focus difference to a predetermined threshold value.
